(19) United States
(12) Patent Application Publication
(10) Pub. No.: US 2025/0201466 A1
(43) Pub. Date: Jun. 19, 2025

(54) VOLTAGE-ISOLATED IC PACKAGES WITH EXTENSIONS FOR CORE PLACEMENT

(71) Applicant: Allegro MicroSystems, LLC, Manchester, NH (US)

(72) Inventors: Vijay Mangtani, Nashua, NH (US); William P. Taylor, Amherst, NH (US)

(73) Assignee: Allegro MicroSystems, LLC, Manchester, NH (US)

(21) Appl. No.: 18/537,906

(22) Filed: Dec. 13, 2023

(51) Int. Cl. H01F 27/28; H01F 41/04; H01L 23/31; H05K 1/03; H05K 1/11; H05K 1/16

(52) U.S. Cl. CPC H01F 27/2804; H01F 27/2823; H01F 41/046; H01L 23/3107; H05K 1/0306; H05K 1/115; H05K 1/165; H05K 2201/086

(57) ABSTRACT

Aspects of the present disclosure include systems, structures, circuits, and methods providing voltage-isolation transformers having substrate extensions for the transformer core. First and second substrates are configured about a magnetic core and first and second transformer coils. The first substrate can have a recess for receiving the magnetic core. The second substrate can include a protruding member designed to fit within an aperture of the core to facilitate placement or centering of the core. The second substrate is disposed to cover the recess of the first substrate. The packages and modules may include various types of circuits; in some examples, chip packages or modules may include a galvanically isolated gate driver or other high voltage circuit.

### BACKGROUND

Solid state switches typically include a transistor structure. The controlling electrode of the switch, usually referred to as its gate (or base), is typically controlled (driven) by a switch drive circuit, sometimes also referred to as gate drive circuit. Such solid state switches are typically voltage-controlled, turning on when the gate voltage exceeds a manufacturer-specific threshold voltage by a margin, and turning off when the gate voltage remains below the threshold voltage by a margin.

Switch drive circuits typically receive their control instructions from a controller such as a pulse-width-modulated (PWM) controller via one or more switch driver inputs. Switch drive circuits deliver their drive signals directly (or indirectly via networks of active and passive components) to the respective terminals of the switch (gate and source).

Some electronic systems, including ones with solid state switches, have employed galvanic isolation to prevent undesirable DC currents flowing from one side of an isolation barrier to the other. Such galvanic isolation can be used to separate circuits in order to protect users from coming into direct contact with hazardous voltages.

Various transmission techniques are available for signals to be sent across galvanic isolation barriers including optical, capacitive, and magnetic coupling techniques. Magnetic coupling typically relies on use of a transformer to magnetically couple circuits on the different sides of the transformer, typically referred to as the primary and secondary sides, while also providing galvanic separation of the circuits.

Transformers used for magnetic-coupling isolation barriers typically utilize a magnetic core to provide a magnetic path to channel flux created by the currents flowing in the primary and secondary sides of the transformer. Magnetic-coupling isolation barriers have been shown to have various drawbacks, including manufacturing problems, for integrated circuit (IC) packages due to the included magnetic core.

### SUMMARY

Aspect of the present disclosure are directed to isolation transformer packages and voltage-isolated integrated circuit (IC) packages having extensions for core placement.

One general aspect of the present disclosure includes a voltage-isolated (galvanically-isolated) integrated circuit (IC) package. The voltage-isolated IC package can include: a first substrate having opposed first and second surfaces, where the first substrate includes a recess disposed in the first surface, and where the recess has a perimeter; first and second semiconductor die supported by the first substrate; a magnetic core disposed in the recess, where the magnetic core includes soft ferromagnetic material and an inner surface; and a second substrate having opposed first and second surfaces, where the second substrate is disposed on the first surface of the first substrate and covering the recess, where the second substrate includes a protruding member extending from the second surface, and where the protruding member is configured to fit within the inner surface of the magnetic core; first and second coils disposed about the magnetic core and connected to the first and second semiconductor die, respectively, where the first and second coils and magnetic core are configured as a transformer; and first and second lead sets connected to the first and second semiconductor die, respectively.

Implementations may include one or more of the following features. The voltage-isolated IC package may include an encapsulant covering the second substrate and defining a surface of a package body. The encapsulant may include a mold material. The encapsulant may include an insulator material. The first and second coils may include wire bonds. The first and second coils each may include first portions disposed in or on the first substrate and second portions disposed in or on the second substrate. The first portions and/or second portions may include one or more vias disposed in the first or second substrate, respectively. The transformer can be configured to provide magnetic coupling and galvanic separation between the first and second semiconductor die. The first substrate and/or second substrate may include a printed circuit board (PCB) and/or PCB material(s) (e.g., FR-4, FR-5, etc.). The first substrate and/or second substrate may include one or more layers of low-temperature cofired ceramic (LTCC) or high-temperature cofired ceramic (HTCC). The first substrate and/or second substrate may include an alumina substrate. The first substrate and/or second substrate may include a glass substrate, e.g., having one or more layers of metal and insulation/glass. The magnetic core may include ferrite. The magnetic core may include a nickel-iron alloy, ferrosilicon and/or another suitable soft (magnetic property) ferromagnetic material. The magnetic core may include a closed shape having an aperture. The protruding member can include a cross section that decreases with distance from the second surface of the second substrate, where the protruding member is configured to position (e.g., center) the magnetic core within the recess.

Another general aspect of the present disclosure includes a method of making a voltage-isolated (galvanically-isolated) integrated circuit (IC) package. The method can include: providing a first substrate having opposed first and second surfaces, where the first substrate includes a recess disposed in the first surface, and where the recess has a perimeter; providing first and second semiconductor die supported by the first substrate; providing a magnetic core disposed in the recess, where the magnetic core includes soft ferromagnetic material and an inner surface; and providing a second substrate having opposed first and second surfaces and disposed on the first surface of the first substrate, where the second substrate covers the recess, where the second substrate includes a protruding member extending from the second surface, and where the protruding member is configured to fit within the inner surface of the magnetic core; providing first and second coils disposed about the magnetic core; where the first and second coils and magnetic core are configured as a transformer; and providing first and second lead sets connected to the first and second semiconductor die, respectively.

Implementations may include one or more of the following features. The method may include applying an encapsulant covering the second substrate and defining a surface of a package body. The encapsulant may include a molding material. The first and second coils may include wire bonds. The first and second coils each may include first portions disposed in or on the first substrate and second portions disposed in or on the second substrate. Providing the first and second coils may include providing a first plurality of vias for the first coil and a second plurality of vias for the second coil. The first plurality of vias may include one or more vias disposed in the first substrate. The first plurality of vias may include one or more vias disposed in the second substrate. The second plurality of vias may include one or more vias disposed in the first substrate. The second plurality of vias may include one or more vias disposed in the second substrate. Providing the first plurality of vias for the first coil and the second plurality of vias for the second coil may include drilling and/or plating through holes in the first substrate and/or second substrate. The transformer can be configured to provide magnetic coupling and galvanic separation between the first and second semiconductor die. The first substrate and/or second substrate may include a printed circuit board (PCB) and/or PCB material(s), e.g., FR-4, FR-5, etc. The first substrate and/or second substrate may include one or more layers of low-temperature cofired ceramic (LTCC) or high-temperature cofired ceramic (HTCC). The first substrate and/or second substrate may include an alumina substrate. The first substrate and/or second substrate may include a glass substrate, e.g., having one or more layers of metal and insulation/glass. The magnetic core may include ferrite. The magnetic core may include a nickel-iron alloy or ferrosilicon or another suitable soft (magnetic property) ferromagnetic material.

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the present disclosure, which is susceptible of many embodiments. What follows is illustrative, but not exhaustive, of the scope of the present disclosure.

### BRIEF DESCRIPTION OF THE DRAWINGS

The manner and process of making and using the disclosed embodiments may be appreciated by reference to the figures of the accompanying drawings. In the figures like reference characters refer to like components, parts, elements, or steps/actions; however, similar components, parts, elements, and steps/actions may be referenced by different reference characters in different figures. It should be appreciated that the components and structures illustrated in the figures are not necessarily to scale, emphasis instead being placed upon illustrating the principals of the concepts described herein. Furthermore, embodiments are illustrated by way of example and not limitation in the figures, in which:

FIG. 1 is a diagram showing a side view of an example transformer package structure having an extension structure for core placement, in accordance with the present disclosure;

FIG. 2 is a diagram showing a side view of an example voltage-isolated IC package structure having an extension structure for core placement, in accordance with the present disclosure;

FIGS. 3A-3B are top views of example voltage-isolated IC packages having extensions for core placement in accordance with the present disclosure; FIG. 3A shows a package with windings utilizing wire bonds and FIG. 3B shows a package with windings formed by a combination of traces and vias; and

FIG. 4 is a box diagram showing an example method of fabricating a voltage-isolated IC package having an extension structure for core placement, in accordance with the present disclosure.

### DETAILED DESCRIPTION

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The subject technology is susceptible of many embodiments. What follows is illustrative, but not exhaustive, of the scope of the subject technology.

Aspects of the present disclosure are directed to and include systems, structures, circuits, and methods providing transformers and transformer structures having extension structures that can be used for core placement. Embodiments and examples can include one or more ICs, which can be galvanically isolated by the transformers or transformer structures. In some embodiments, a transformer may have, e.g., a step up, a step down, or a power transformer configuration. Some embodiments and examples can include transformers and IC as integrated circuit transformer-IC packages. Some embodiments and examples can include transformers in transformer packages and structures (e.g., substrates without a package body or protective layer/material) with or without one or more ICs.

The packages and modules may include various types of circuits; in some examples, IC packages or modules may include one or more (e.g., first and second) semiconductor die having one or more integrated circuits (a.k.a., “IC die”). Such integrated circuits can include, e.g., but are not limited to, high-voltage circuits such as galvanically-isolated gate drivers configured to drive an external gate on a solid-state switch, e.g., a field effect transistor (FET), a metal oxide FET (MOSFET), a metal semiconductor FET (MESFET), a gallium nitride FET (GaNFET), a silicon carbide FET (SiCFET), an insulated gate bipolar transistor (IGBT), or another load.

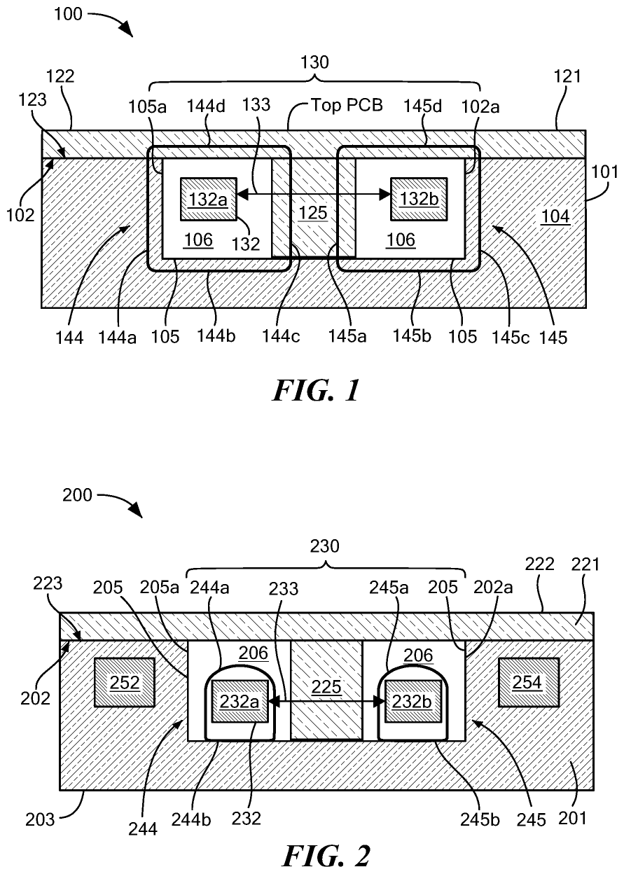

FIG. 1 is a diagram showing a side view of an example transformer package structure 100 having an extension structure for core placement, in accordance with the present disclosure. Structure 100 can include a first substrate 101 having opposed first and second sides (surfaces) 102 and 103. Substrate 101 can include any suitable substrate material 104, e.g., a PCB material, a ceramic substrate material (e.g., low-temperature cofired ceramic or high-temperature cofired ceramic), glass material with alternating metal layers, etc. In some embodiments, substrate 101 can include a PCB including FR4 or FR5. Substrate 101 can include a recessed surface 105 forming a recess (a.k.a., cavity) 106. Recessed surface 105 can define or have a perimeter 105a, e.g., at an aperture 102a in first surface 102. Recess 106 can be configured to receive a magnetic core, as described in further detail below.

Structure 100 can include a magnetic core 132 (shown with cross sections 132a-b), which may have a closed shape, e.g., toroidal or rectangular. Core 132 may be disposed in recess/cavity 106. Core 132 may include one or more soft ferromagnetic materials, e.g., ferrite, a nickel alloy, NiFe, SiFe (ferrosilicon), etc.

Structure 100 may further include a second substrate 121 (shown as the top substrate) having first and second opposed sides (surface) 122, 123. Second substrate 121 may be disposed on first surface 102 of first substrate 101, e.g., such that cavity 106 is covered, as shown. Second substrate 121 can have an attached or integrated (integral) protruding member or structure 125, e.g., on second side 123 as shown. Protruding structure or member 125 (a.k.a., “extension structure,” “extending member,” “protrusion,” or “extension”) can be configured to extend/protrude into recess 106 and within an inner region or space 133 (indicated by diameter or dimension shown with arrow) bounded by core 132. For example, in an embodiment where core 132 has a toroidal shape (a.k.a., a doughnut shape), space 133 (accommodating or receiving structure/protruding member 125) is shown defined or bounded by the closed shape of core 132 (i.e., within the “doughnut hole” region with a diameter indicted by 133). In some embodiments, protruding member (extension) 125 can be tapered, e.g., have a cross section that decreases with distance from the second surface 123 of the second substrate 121. Protruding member 125 can facilitate positioning of core 132 during fabrication and/or operation of structure 100.

In some embodiments, protruding member (extension) on the top or second substrate (e.g., PCB) may be made from PCB layers attached to the second substrate by an adhesive, e.g., a non-conductive adhesive, tape, etc. In other embodiments, protruding member (extension) 125 may be made from a plastic material, which can be molded. In some embodiments, a molded extension 125 can be solid; in some embodiments, a molded extension 125 can be open on one side, e.g., an open cylinder or a wall having a desired shape with an open end. In some embodiments, open side (indicated as 125a) of molded extension 125 can be connected/attached to the second (top) substrate 121, e.g., at surface 123. In some embodiments, extension 125 can be attached to the second substrate 121 with, e.g., an adhesive or tape at one or more locations (or continuously) around the perimeter of extension 125.

Structure 100 can include conductive structures forming first and second transformer coils 144 and 145, respectively. Coils 144 (shown with connected portions 144a-d) and 145 (shown with connected portions 145a-d) may each have components or portions that are joined (connected), e.g., conductive traces and/or vias, posts, plated through-holes, etc. For example, coil 144 is shown with vias 144a and 144c (disposed in first substrate 101 and protruding member 125, respectively, and conductive traces 144d and 144b (disposed in or on second substrate 121 and first substrate 101, respectively). Coil 145 is shown with vias 145a and 145c (disposed in protruding member 125 and first substrate 101, respectively) and conductive traces 145d and 145b (disposed in or on second substrate 121 and first substrate 101, respectively).

Each of the first and second coils 144, 145 may have a desired number of windings (e.g., with a winding pitch extending into and/or out of the plane of the figure). The coils 144, 145 and core 132 can be configured as a transformer 130. Transformer 130 may have a step up configuration in some embodiments, a step down configuration in some embodiments, and a power transformer configuration in some embodiments.

While FIG. 1 shows structure with coil windings formed by conductive traces and vias, some embodiments may include wires and/or wire bonds for one or more portions or complete windings of transformer coils.

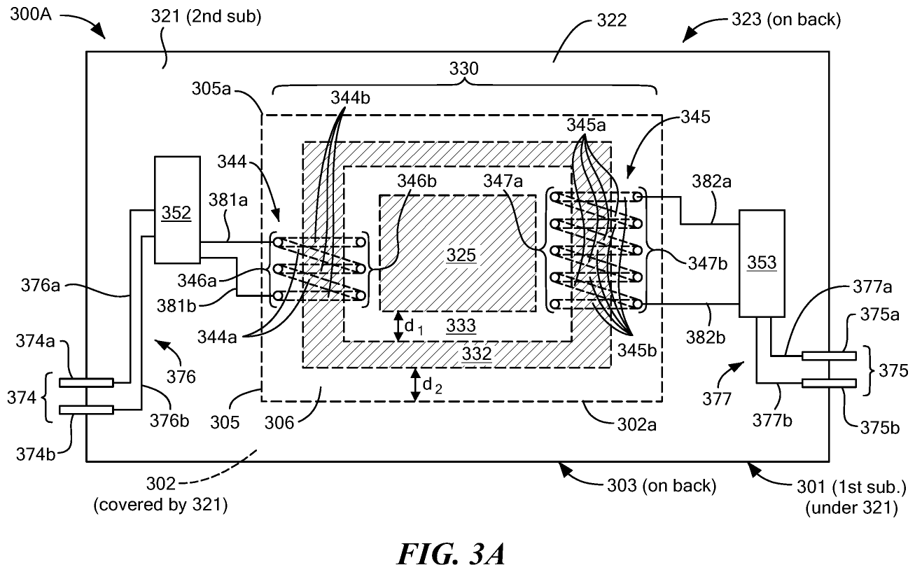

FIG. 2 is a diagram showing a side view of an example voltage-isolated IC package structure 200 having an extension structure for core placement, in accordance with the present disclosure. Structure 200 can include a first substrate 201 having opposed first and second sides (surfaces) 202 and 203. Substrate 201 can include a recessed surface 205 forming a recess (a.k.a., cavity) 206. Recessed surface 205 can define or have a perimeter 205a, e.g., at an aperture 202a in first surface 202. Substrate 221 with protruding member 225 can be disposed over top surface 202 of first substrate 201, covering recess 206.

Structure 200 includes a transformer 230 with magnetic core 232 and first and second coils 244, 245. Magnetic core 232 (shown with cross sections 232a-b) can be disposed in recess 206, as shown. Protruding member 225 can be configured to extend into recess 206 and within an inner region of core 232, e.g., an inner radial region or space 233 (indicated by dimension or diameter 233) defined by the closed shape of the core, as shown. Protruding member 225 can facilitate positioning of core 232, e.g., during fabrication and/or operation of structure 200. Substrate 201 and substrate 221 can include or be formed from any suitable substrate material, e.g., a PCB substrate, a ceramic substrate material (e.g., low-temperature cofired ceramic or high-temperature cofired ceramic), glass substrate having glass material with alternating metal layers, etc. In some embodiments, a different material may be used for each substrate.

First and second coils 244, 245 can be configured (e.g., wound) about core 232 for transformer 230. Coils 244 and 245 can include wire or wire bonds (insulated or uninsulated) 244a, 245a as portions. Coils 244 and 245 can also include conductive traces 244b, 245b as portions. An insulative material (not shown) is preferably present between core 232 and conductive traces 244b, 245b. In some embodiment, insulative (dielectric) material may be part of the first substrate (e.g., PCB) 201, in which case, only wire bond areas are open and an insulating PCB layer is under the core area. In embodiments where the traces 244b, 245b (lower winding portions) are exposed, non-conductive epoxy, or a tape may be used as insulator material. Each of the first and second coils 244, 245 may have a desired number of windings (e.g., with a winding pitch extending into and/or out of the plane of the figure). In some embodiments, a protective material may be placed over the wire bonds 244a, 245a to protect them during, e.g., during assembly with the second (top) substrate 221 and/or during operation of the package structure 200. As shown, first and second ICs, e.g., shown as IC die packages 252, 254, can be connected to first and second coils 244 and 245, respectively, on galvanically separated sides (e.g., primary and secondary sides) of transformer 230.

In some embodiments, transformer 230 can be constructed with wire bonds, as described above, but on the second (top) substrate 221. The protruding member (extension) 225 can be added after wire bonding the transformer 230. In some embodiments, core 232 may be attached to the first substrate 201. In some embodiments, core 232 may be attached to the second substrate 221. In some embodiments, core 232 is not necessarily fixedly attached to a substrate but may be positioned within recess/cavity 206 without attachment structure/material(s), e.g., in a “floating” configuration. In some embodiments, core 232 may have silicone gel or dielectric gel supplied to the inner radial region/space 233. For embodiments in which the protruding member (extension) 225 includes a plastic or molded material (e.g., that is glued or adhered to the second substrate 221), the wire bonds may be covered with a gel before or after attachment. The second (top) substrate 221 can then be position on the first substrate 201, with protruding member (extension) 225 and core 232 inserted into the recess in first substrate 201.

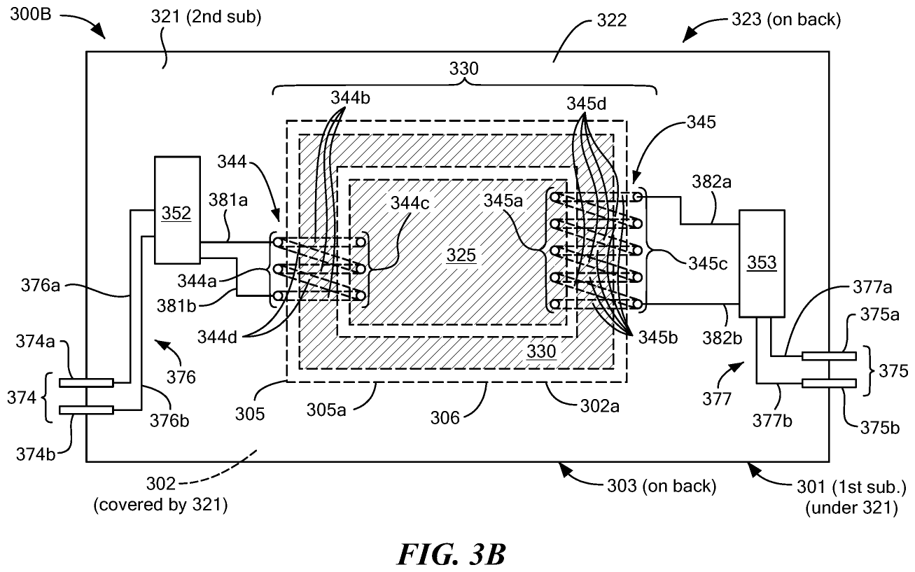

FIGS. 3A-3B are top views of example voltage-isolated IC packages having extensions for core placement in accordance with the present disclosure. FIG. 3A shows a package 300A with windings utilizing wire bonds and FIG. 3B shows a package 300B with windings formed by a combination of traces and vias.

As shown in FIG. 3A, package structure 300A can include a first substrate 301 covered by a second substrate 321. Substrate 301 can have opposed first and second sides (surfaces) 302 and 303. Substrate 321 can have opposed first and second sides 322 and 323. Substrate 301 can include a recessed surface 305 forming a recess (a.k.a., cavity) 306. Recessed surface 305 can define or have a perimeter 305a, e.g., at an aperture 302a in first surface 302. As shown, substrate 321 with protruding member 325 can be disposed over top surface 302 of first substrate 301, covering recess 306. Substrate 301 and substrate 321 can include or be formed from any suitable substrate material, e.g., a PCB material, a ceramic substrate material (e.g., low-temperature cofired ceramic or high-temperature cofired ceramic), glass material with alternating metal layers, etc.

Structure 300A includes a transformer 330 with magnetic core 332 and coils 344, 345. Magnetic core 332 can be disposed in recess 306, as shown. Protruding member 325 can be configured to extend into recess 306 and within an inner (radial) region of core 332, e.g., an aperture or space 333 (indicated by diameter or dimensions 333) defined or bounded by the closed shape of the core 332, as shown. Protruding member 325 and/or core 332 may be configured (e.g., designed or sized) to provide a desired or nominal distance between core 332 and member 325 (e.g., as indicated by d₁) and/or between core 332 and surface 305 (e.g., as indicated by d₂). While protruding member 325 is shown having a shape that is similar to or generally matching that of core 332 (and the outline of region or space 333), protruding member 325 can have other shapes in other embodiments, e.g., one having an outline different than that of space 333. Protruding member 325 can facilitate positioning of core 332, e.g., during fabrication and/or operation of structure 300A.

First and second coils 344, 345 can be configured (wound) about core 332 for transformer 330. Coils 344 and 345 can include wire or wire bonds 344a, 345a, respectively, as portions (e.g., first portions). Coils 344 and 345 can also include conductive traces 344b, 345b, respectively, as portions (e.g., second portions). Insulator material is preferably present between core 332 and conductive traces 344b, 345b. The wire bonds and conductive traces may be connected by suitable connections, as shown by solder connections 346a-b and 347a-b. Each of the first and second coils 344, 345 may have a desired number of windings (e.g., with a winding pitch extending into and/or out of the plane of the figure). Transformer 330 may have a desired configuration, e.g., one as a step up transformer, a step down transformer, or a power transformer.

Structure 300A can include first and second IC die 352 and 353 (indicated by IC die packages), as shown. First and second IC die 352, 353 can be connected to first and second coils 344, 345 by suitable connections, e.g., as shown by sets of conductive traces 381a-b and 382a-b, respectively. IC die 352 and first coil 344 can be on one side of transformer 330, e.g., a primary side, while IC die 353 and second coil 345 can be on the other side of transformer 330, e.g., a secondary side. Conductive structures—shown as lead sets 374, 375 with accompanying conductive paths (wires) 376 and 377—can provide input/output connections to IC die 352, 353 and/or other portions of primary and secondary sides of transformer 330, respectively. While lead sets 374, 375 are each shown with two leads (374a-b and 375a-b) connected to conductive paths/wires 376a-b and 377a-b, respectively, they may have any practical number of leads (and connecting conductive paths/wires) and/or different configurations in other embodiments and examples. In some examples, a land grid array (or other structures) can be used instead of or in addition to lead sets 374, 375. In some embodiments, an optional encapsulant (encapsulation) layer of suitable encapsulant material may be positioned to cover second substrate 321. Suitable encapsulants can include, but are not limited to, molding (mold) materials, protective materials (e.g., silicone gel), and dielectric (insulator) materials. Encapsulant material can be used for forming a package body, e.g., can define one or more surfaces of a package body.

As shown in FIG. 3B, structure 300B can include a first substrate 301 covered by a second substrate 321. Substrate 301 can have opposed first and second sides (surfaces) 302 and 303. Substrate 321 can have opposed first and second sides 322 and 323. Substrate 301 can include a recessed surface 305 forming a recess (a.k.a., cavity) 306. Recessed surface 305 can define or have a perimeter 305a, e.g., at an aperture 302a in first surface 302. As shown, substrate 321 with protruding member 325 can be disposed overtop surface 302 of first substrate 301, covering recess 306. Substrate 301 and substrate 321 can include or be formed from any suitable substrate material, e.g., a PCB material, a ceramic substrate material (e.g., low-temperature cofired ceramic or high-temperature cofired ceramic), glass material with alternating metal layers, etc.

Structure 300B includes a transformer 330 with magnetic core 332 and coils 344, 345. Magnetic core 332 can be disposed in recess 306, as shown. Protruding member 325 can be configured to extend into recess 306 and within an inner region of core 332, e.g., a space 333 defined or bounded by the closed shape of the core 332, as shown. Protruding member 325 and/or core 332 may be configured (e.g., designed or sized) to provide a desired or nominal distance between core 332 and member 325 and/or between core 332 and surface 305. While protruding member 325 is shown having a shape that is similar to or generally matching that of core 332 (and the outline of space 333), protruding member 325 can have other shapes in other embodiments, e.g., one having an outline different than that of space 333. Protruding member 325 can facilitate positioning of core 332, e.g., during fabrication and/or operation of structure 300B.

First and second coils 344, 345 can be configured (wound) about core 332 for transformer 330. Coils 344 and 345 can include or be composed of conductive structures in and/or substrates 301 and 321 including protruding member 325. For example, coil 344 can have multiple connected portions, including vias (or posts, columns, or plated/filled through holes) 344a and 344c in first substrate 301 and protruding member 325, respectively, and also including conductive traces 344b and 344d in and/or on first substrate 301 and second substrate 321, respectively. Similarly, coil 345 can have multiple connected portions, including vias (or posts, columns, or plated/filled through holes) 345a and 345c in protruding member 325 and first substrate 301, respectively, and also including conductive traces 345b and 345d in and/or on first substrate 301 and second substrate 321, respectively. The coil portions can be connected by suitable connections, e.g., solder connections. Each of the first and second coils 344, 345 may have a desired number of windings (e.g., with a winding pitch extending into and/or out of the plane of the figure). Insulator material is preferably present between conductive traces (344b, 344d and 345b, 345d) and core 332.

Structure 300B can include first and second IC die 352 and 353 (indicated by IC die packages), as shown. First and second IC die 352, 353 can be connected to first and second coils 344, 345 by suitable connections, e.g., as shown by sets of conductive traces 381a-b and 382a-b, respectively. IC die 352 and first coil 344 can be on one side of transformer 330, e.g., a primary side, while IC die 353 and second coil 345 can be on the other side of transformer 330, e.g., a secondary side. Conductive structures-shown as lead sets 374, 375 with accompanying conductive paths (wires) 376 and 377—can provide input/output connections to IC die 352, 353 and/or other portions of primary and secondary sides of transformer 330, respectively. While lead sets 374, 375 are each shown with two leads (374a-b and 375a-b) connected to conductive paths/wires 376a-b and 377a-b, respectively, they may have any practical number of leads (and accompanying connecting wires/paths) and/or different configurations in other embodiments and examples. In some examples, a land grid array (or other structures) can be used instead of or in addition to lead sets 374, 375. In some embodiments, an optional encapsulant layer of suitable encapsulant material may be positioned to cover second substrate 321. Suitable encapsulants can include, but are not limited to, molding (mold) materials, protective materials (e.g., silicone gel), and dielectric (insulator) materials. Encapsulant material can be used for forming a package body, e.g., can define one or more surfaces of a package body.

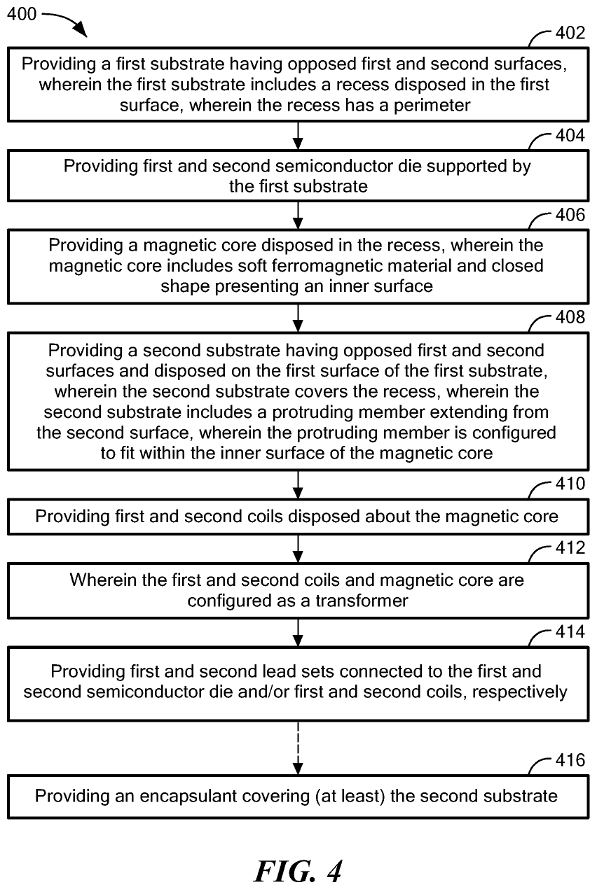

FIG. 4 is a box diagram showing an example method 400 of fabricating a voltage-isolated IC package having an extension structure for core placement, in accordance with the present disclosure. Method 400 can include providing a first substrate having opposed first and second surfaces, where the first substrate includes a recess disposed in the first surface, where the recess has a perimeter, as described at 402. The first substrate can be composed of or include any suitable substrate material(s), e.g., PCB, ceramic, glass, etc. First and second semiconductor die can be provided that are supported by the first substrate, as described at 404. A magnetic core can be provided that is disposed in the recess, with the magnetic core including a soft ferromagnetic material and having a closed shape presenting an inner surface (e.g., inner radial surface), as described at 406.

A second substrate can be provided that has opposed first and second surfaces and that is disposed on the first surface of the first substrate, with the second substrate covering the recess, and with the second substrate includes a protruding member extending from the second surface; the protruding member can be configured to fit within the inner surface of the magnetic core, as described at 408. First and second coils can be provided that are disposed about the magnetic core, as described at 410. Each of the first and second coils may have a desired number of windings. Each of the first and second coils may have multiple connection portions of suitable conductive structure, e.g., wire bonds, conductive traces, vias, plated through holes, etc. The first and second coils and magnetic core can be configured as a transformer, as described at 412. The transformer may be configured as: a step up transformer in some embodiments, a step down transformer in some embodiments, and a power transformer in some embodiments.

Method 400 can include providing first and second lead sets connected to the first and second semiconductor die and/or first and second coils, respectively, as described at 414. As an optional step, an encapsulant may be provided covering (at least) the second substrate, e.g., as described at 416. Any suitable encapsulant may be provided, e.g., a molding material, a soft compliant protective material, a dielectric material, etc. In some embodiments, e.g., ones including a molding material or materials as encapsulant(s), such material(s) may form or define one or more surfaces of a package body.

In some embodiments, an insulator material can be provided to the magnetic core to provide isolation. In some embodiments, the core may be insulated with an insulating tape on the core side(s)/surface(s) facing an adjacent substrate.

In some examples, a voltage-isolated IC package may include a gate driver that is galvanically isolated by the transformer structure. The first and second coils and first and second IC die along with connecting conductive structure can form primary (input) and secondary (output) sides, respectively, of a transformer. In some embodiments and examples, the secondary side (e.g., with gate driver) may be a high (higher) voltage side, with the transformer configured as a step up transformer.

In some examples and/or embodiments, integrated circuits (ICs) in die or other conductive features of the primary and secondary sides of a transformer structure, in or connected to the main body can be fabricated or configured to have a desired separation distance (d) between certain parts or features, e.g., to meet internal creepage or external clearance requirements for a given pollution degree rating as defined by certain safety standards bodies such as the Underwriters Laboratories (UL) and the International Electrotechnical Commission (IEC). For example, a separation distance may be between closest (voltage) points of the respective circuits, e.g., the low-voltage (primary) side and high-voltage (secondary) side. For further example, such a separation distance may be the distance between any two voltage points between the primary and secondary sides, or a distance between die, or a distance between exposed leads, may be or may be at least 1.2 mm, 1.4 mm, 1.5 mm, 3.0 mm, 4.0 mm, 5.5 mm, 7.2 mm, 8.0 mm, 10 mm, or 10+ mm in respective examples. Such a distance between conductive portions or areas of die can include any insulation covering a conductor, e.g., such as plastic coating of a wire/lead. Other distances between conductive parts, components, and/or features of an IC package may also be designed and implemented, e.g., to meet desired internal creepage, voltage breakdown, or external clearance requirements.

In some examples and embodiments, a dielectric material (e.g., gel) may be used for potting and/or protecting substrate (e.g., PCB) systems, assemblies, and/or packages to protect die, cores and/or interconnects from environment conditions and/or to provide dielectric insulation. In some examples, a dielectric material may include, but is not limited to, one or more of the following materials: DOWSIL™ EG-3810 Dielectric Gel (made available by The Dow Chemical Corporation, a.k.a., “Dow”, and DOWSIL™ EG-3896 Dielectric Gel (made available by Dow), which has the ability to provide isolation greater than 20 kV/mm. Other suitable gel materials may also or instead be used, e.g., to meet or facilitate meeting/achieving voltage isolation specifications required by a given package design. DOWSIL™ EG-3810 is designed for temperature ranges from −60° C. to 200° C. and DOWSIL™ EG-3896 Dielectric Gel −40° C. to +185° C.; both of which can be used to meet typical temperature ranges for automotive applications.

Accordingly, embodiments and/or examples of the inventive subject matter can afford various benefits relative to prior art techniques. For example, embodiments and examples of the present disclosure can enable or facilitate use of smaller size packages for a given power or voltage rating. Embodiments and examples of the present disclosure can enable or facilitate lower costs and higher scalability for manufacturing of IC packages/modules having voltage-isolated IC die and transformers.

Various embodiments of the concepts, systems, devices, structures, and techniques sought to be protected are described above with reference to the related drawings. Alternative embodiments can be devised without departing from the scope of the concepts, systems, devices, structures, and techniques described.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

Additionally, the term “exemplary” means “serving as an example, instance, or illustration.” Any embodiment or design described as “exemplary” is not necessarily to be construed as preferred or advantageous over other embodiments or designs. The terms “one or more,” “plurality,” and “at least one” indicate any integer number greater than or equal to one, i.e., one, two, three, four, etc.; however, those terms may refer to fractional numbers where context admits, e.g., a number of loops in a transformer coil) may be a fractional value, e.g., 2.75, 3.5, 4.25, etc. The term “connection” can include an indirect “connection” and a direct “connection.”

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases do not necessarily refer to the same embodiment. Further, when a particular feature, structure, or characteristic is described in connection with an embodiment, it may affect such feature, structure, or characteristic in other embodiments whether explicitly described or not.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed but are used merely as labels to distinguish one claim element having a certain name from another element having a same name (but for use of the ordinal term) to distinguish the claim elements.

The terms “approximately” and “about” may be used to mean within ±20% of a target (or nominal) value in some embodiments, within plus or minus (±) 10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within +5% of one another in some embodiments, and yet within ±2% of one another in some embodiments.

The term “substantially” may be used to refer to values that are within ±20% of a comparative measure in some embodiments, within +10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and carried out in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions as far as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

What is claimed is:

1. A voltage-isolated integrated circuit (IC) package comprising:
a first substrate having opposed first and second surfaces, wherein the first substrate includes a recess disposed in the first surface, and wherein the recess has a perimeter;
first and second semiconductor die supported by the first substrate;
a magnetic core disposed in the recess, wherein the magnetic core includes soft ferromagnetic material and an inner surface; and
a second substrate having opposed first and second surfaces, wherein the second substrate is disposed on the first surface of the first substrate and covering the recess, wherein the second substrate includes a protruding member extending from the second surface, and wherein the protruding member is configured to fit within the inner surface of the magnetic core;
first and second coils disposed about the magnetic core and connected to the first and second semiconductor die, respectively, wherein the first and second coils and magnetic core are configured as a transformer; and
first and second lead sets connected to the first and second semiconductor die, respectively.

2. The voltage-isolated IC package of claim 1, further comprising an encapsulant covering the second substrate and defining a surface of a package body.

3. The voltage-isolated IC package of claim 2, wherein the encapsulant comprises a mold material.

4. The voltage-isolated IC package of claim 1, wherein the first and second coils comprise wire bonds.

5. The voltage-isolated IC package of claim 1, wherein the first and second coils each comprise first portions disposed in or on the first substrate and second portions disposed in or on the second substrate.

6. The voltage-isolated IC package of claim 5, wherein the first portions and/or second portions comprises one or more vias disposed in the first or second substrate, respectively.

7. The voltage-isolated IC package of claim 1, wherein the transformer is configured to provide magnetic coupling and galvanic separation between the first and second semiconductor die.

8. The voltage-isolated IC package of claim 1, wherein the first substrate and/or second substrate comprises a printed circuit board (PCB).

9. The voltage-isolated IC package of claim 1, wherein the first substrate and/or second substrate comprises one or more layers of low-temperature cofired ceramic (LTCC) or high-temperature cofired ceramic (HTCC).

10. The voltage-isolated IC package of claim 1, wherein the first substrate and/or second substrate comprises an alumina substrate.

11. The voltage-isolated IC package of claim 1, wherein the first substrate and/or second substrate comprises a glass substrate comprising one or more layers of metal and insulation.

12. The voltage-isolated IC package of claim 2, wherein the encapsulant comprises an insulator material.

13. The voltage-isolated IC package of claim 1, wherein the magnetic core comprises ferrite.

14. The voltage-isolated IC package of claim 1, wherein the magnetic core comprises a nickel-iron alloy.

15. The voltage-isolated IC package of claim 1, wherein the magnetic core includes a closed shape having an aperture.

16. The voltage-isolated IC package of claim 15, wherein the protruding member includes a cross section that decreases with distance from the second surface of the second substrate, and wherein the protruding member is configured to position the magnetic core within the recess.

17. A method of making a voltage-isolated integrated circuit (IC) package, the method comprising:
providing a first substrate having opposed first and second surfaces, wherein the first substrate includes a recess disposed in the first surface, and wherein the recess has a perimeter;
providing first and second semiconductor die supported by the first substrate;
providing a magnetic core disposed in the recess, wherein the magnetic core includes soft ferromagnetic material and an inner surface; and
providing a second substrate having opposed first and second surfaces and disposed on the first surface of the first substrate, wherein the second substrate covers the recess, wherein the second substrate includes a protruding member extending from the second surface, and wherein the protruding member is configured to fit within the inner surface of the magnetic core;
providing first and second coils disposed about the magnetic core;
wherein the first and second coils and magnetic core are configured as a transformer; and
providing first and second lead sets connected to the first and second semiconductor die, respectively.

18. The method of claim 17, further comprising applying an encapsulant covering the second substrate and defining a surface of a package body.

19. The method of claim 18, wherein the encapsulant comprises a molding material.

20. The method of claim 17, wherein the first and second coils comprise wire bonds.

21. The method of claim 17, wherein the first and second coils each comprise first portions disposed in or on the first substrate and second portions disposed in or on the second substrate.

22. The method of claim 17, wherein providing the first and second coils comprises providing a first plurality of vias for the first coil and a second plurality of vias for the second coil.

23. The method of claim 22, wherein the first plurality of vias includes one or more vias disposed in the first substrate.

24. The method of claim 22, wherein the first plurality of vias includes one or more vias disposed in the second substrate.

25. The method of claim 22, wherein the second plurality of vias includes one or more vias disposed in the first substrate.

26. The method of claim 22, wherein the second plurality of vias includes one or more vias disposed in the second substrate.

27. The method of claim 22, wherein providing the first plurality of vias for the first coil and the second plurality of vias for the second coil comprises drilling and/or plating through holes in the first substrate and/or second substrate.

28. The method of claim 17, wherein the transformer is configured to provide magnetic coupling and galvanic separation between the first and second semiconductor die.

29. The method of claim 17, wherein the first substrate and/or second substrate comprises a printed circuit board (PCB).

30. The method of claim 17, wherein the first substrate and/or second substrate comprises one or more layers of low-temperature cofired ceramic (LTCC) or high-temperature cofired ceramic (HTCC).

31. The method of claim 17, wherein the first substrate and/or second substrate comprises an alumina substrate.

32. The method of claim 17, wherein the first substrate and/or second substrate comprises a glass substrate comprising one or more layers of metal and insulation.

33. The method of claim 17, wherein the magnetic core comprises ferrite.

34. The method of claim 17, wherein the magnetic core comprises a nickel-iron alloy.
